(19) United States
(12) Patent Application Publication
(10) Pub. No.: US 2012/0326299 A1
(43) Pub. Date: Dec. 27, 2012

(54) SEMICONDUCTOR CHIP WITH DUAL POLYMER FILM INTERCONNECT STRUCTURES

(76) Inventors: Roden R. Topacio, Markham (CA); I-Tseng Lee, Qiaotou Township (TW)

(21) Appl. No.: 13/168,158

(22) Filed: Jun. 24, 2011

(51) Int. Cl. H01L 21/28; H01L 23/485; H01L 23/488; H01L 21/58

(52) U.S. Cl. 257/737; 438/612; 438/614; 438/121; 257/779; 257/E21.158; 257/E21.499; 257/E23.021; 257/E23.023

(57) ABSTRACT

Various semiconductor chip input/output structures and methods of making the same are disclosed. In one aspect, a method of manufacturing is provided that includes applying a first polymer film to a side of a semiconductor chip and forming a first underbump metallization structure with at least a portion on the first polymer film. A second polymer film is applied on the first polymer film with an opening exposing a portion of the first underbump metallization structure.

### BACKGROUND OF THE INVENTION

1. Field of the Invention

This invention relates generally to semiconductor processing, and more particularly to semiconductor chip underbump metallization structures and methods of making the same.

2. Description of the Related Art

Flip-chip mounting schemes have been used to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

In one conventional process, the connection of the solder bump to a particular I/O site of a semiconductor chip entails forming an opening in a top-level dielectric film of a semiconductor chip proximate the I/O site and thereafter depositing metal to establish an underbump metallization (UBM) structure. The outermost dielectric film is typically a passivation film. The solder bump is then metallurgically bonded to the UBM structure by reflow. This conventional UBM structure includes a base, a sidewall and an upper flange that is positioned on the dielectric film.

Flip-chip solder joints may be subjected to mechanical stresses from a variety of sources, such as coefficient of thermal expansion mismatches, ductility differences and circuit board warping. Such stresses can subject the just described conventional UBM structure to bending moments. The effect is somewhat directional in that the stresses tend to be greatest nearer the die edges and corners and fall off with increasing proximity to the die center. The bending moments associated with this so-called edge effect can impose stresses on the dielectric film beneath the UBM structure that, if large enough, can produce fracture.

For a variety of reasons, designers have begun to turn to lead-free solders for solder joint fabrication. Bumps composed from such solders may produce higher stresses than comparably sized lead-based bumps. To counter such stresses, one conventional design uses a polyimide film on the passivation film with the UBM structure positioned on the polyimide film. If the chip includes active traces proximate I/O pads, the UBM structure may overlap such traces and give rise to parasitics.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes applying a first polymer film to a side of a semiconductor chip and forming a first underbump metallization structure with at least a portion on the first polymer film. A second polymer film is applied on the first polymer film with an opening exposing a portion of the first underbump metallization structure.

In accordance with another aspect of an embodiment of the present invention, a method of coupling a semiconductor chip to a circuit board is provided. The semiconductor chip has a first polymer film, a first underbump metallization structure with at least a portion on the first polymer film, and a second polymer film on the first polymer film with an opening exposing a portion of the first underbump metallization structure. The method additionally comprises coupling a solder structure to the first underbump metallization structure and coupling the solder structure to the circuit board.

In accordance with another aspect of an embodiment of the present invention, an apparatus is provided that includes a semiconductor chip and a first polymer film on the semiconductor chip. A first underbump metallization structure is provided with at least a portion on the first polymer film. A second polymer film is on the first polymer film with an opening exposing a portion of the first underbump metallization structure.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted on a circuit board;

FIG. 2 is a sectional view of FIG. 1 taken at section 2-2;

FIG. 3 is a portion of FIG. 2 shown at greater magnification;

FIG. 4 is a sectional view depicting an exemplary formation of an opening to a conductor structure of a semiconductor chip;

FIG. 5 is a sectional view like FIG. 4, but depicting application of a polymer film over the exemplary conductor structure;

FIG. 6 is a sectional view like FIG. 5, but depicting exemplary lithographic masking and exposure of the polymer film;

FIG. 7 is a sectional view like FIG. 6, but depicting exemplary lithographic fabrication of an opening in the polymer film;

FIG. 8 is a sectional view like FIG. 7, but depicting fabrication of an exemplary underbump metallization structure;

FIG. 9 is a sectional view like FIG. 8, but depicting application and masking of another polymer film on the first polymer film;

FIG. 10 is a sectional view like FIG. 9, but schematically depicting exemplary formation of a solder structure on the underbump metallization structure;

FIG. 11 is a plan view of the exemplary underbump metallization and polymer film portion structures;

FIG. 12 is a sectional view like FIG. 10, but schematically depicting alternate exemplary formation of a solder structure on the underbump metallization structure; and

FIG. 13 is a pictorial view depicting mounting of an exemplary semiconductor chip device in an electronic device.

### DETAILED DESCRIPTION OF SPECIFIC EMBODIMENTS

Various embodiments of a semiconductor chip device are described herein. One example includes solder bump connection structures, such as UBM structures, fabricated on respective conductor pads. The UBM structures may be formed on a polymer film. An additional polymer film may be formed on the UBM structures and patterned into individual islands proximate each UBM structure. The polymer islands provide localized solder joint stress protection. Additional details will now be described.

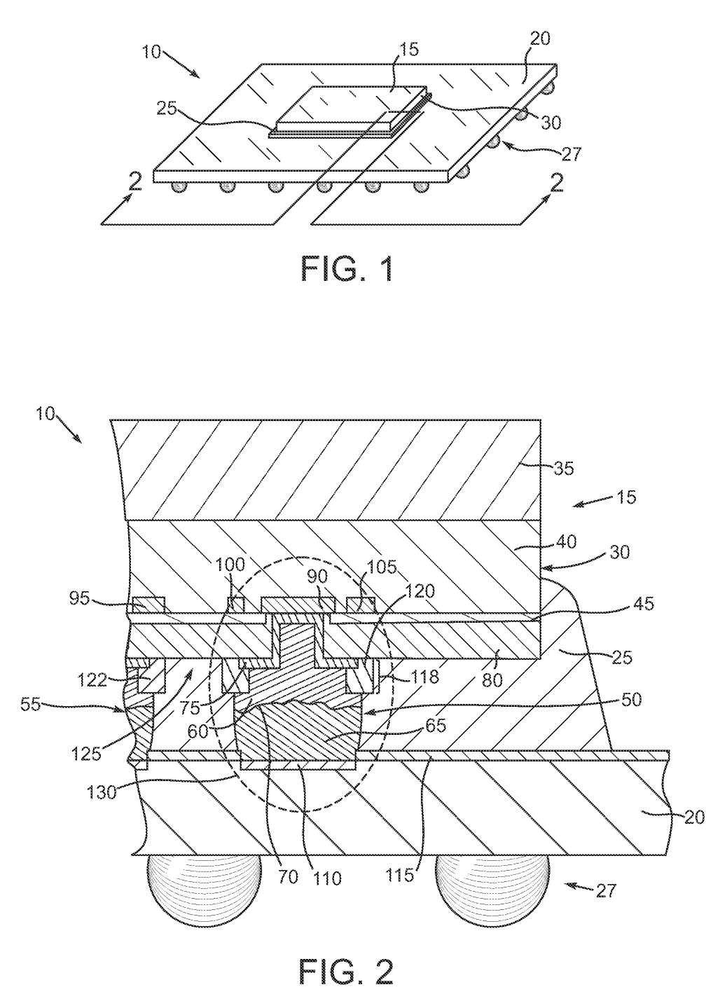

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 mounted on a circuit board 20. An underfill material layer 25 is positioned between the semiconductor chip 15 and the circuit board 20. There are plural solder interconnect structures (not visible) that electrically connect the semiconductor chip 15 to the circuit board 20. The solder interconnect structures disclosed herein are not dependent on particular functionalities of either the semiconductor chip 15 or the circuit board 20. Thus, the semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 15 may be constructed of bulk semiconductor, such as silicon or germanium, or semiconductor on insulator materials, such as silicon-on-insulator materials. The semiconductor chip 15 may be flip-chip mounted to the circuit board 20 and electrically connected thereto by solder joints or other structures (not visible in FIG. 1 but shown in subsequent figures).

The circuit board 20 may be a semiconductor chip package substrate, a circuit card, or virtually any other type of printed circuit board. Although a monolithic structure could be used for the circuit board 20, a more typical configuration will utilize a build-up design. In this regard, the circuit board 20 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards.

The circuit board 20 may be provided with a number of conductor traces and vias and other structures in order to provide power, ground and signals transfers between the semiconductor chip 15 and another circuit device that is not shown in FIG. 1. To facilitate those transfers, the circuit board 20 may be provided with input/outputs in the form of the depicted ball grid array 27, optional pin grid arrays, land grid arrays or other types of interconnect schemes.

Additional details of the semiconductor chip 15 will be described in conjunction with FIG. 2, which is a sectional view of FIG. 1 taken at section 2-2. Before turning to FIG. 2, it will be helpful to note the location of the portion of the semiconductor chip device 10 that will be shown in section. Note that section 2-2 passes through a small portion of the circuit board 20, and a small portion of the semiconductor chip 15 that includes an edge 30. With that backdrop, attention is now turned to FIG. 2. As noted above, the semiconductor chip 15 may be configured as a bulk semiconductor or a semiconductor-on-insulator configuration. In this illustrative embodiment, the semiconductor chip 15 is implemented as bulk semiconductor that includes a bulk semiconductor layer 35, and a semiconductor device layer 40. The semiconductor device layer 40 includes the various circuits that provide the functionality for the semiconductor chip 15 and will typically include plural metallization and/or other types of conductor layers that facilitate the transfer of power, ground and signals to and from the semiconductor chip 15. A passivation structure 45 is formed on the semiconductor device layer 40 and may consist of multiple layers of insulating material. More details regarding the passivation structure 45 will be described in conjunction with a subsequent figure. The semiconductor chip 15 may be flip-chip mounted to the carrier substrate 20 and electrically connected thereto by way of a plurality of solder interconnect structures or joints, two of which are visible and labeled 50 and 55, respectively. Only a portion of the solder joint 55 is visible due to the positioning of section 2-2.

The underfill material layer 25 is dispersed between the semiconductor chip 15 and the substrate 20 to reduce the effects of differences in the coefficients of thermal expansion (CTE) of the semiconductor chip 15, the solder joints 50, 55 etc. and the circuit board 20. The underfill material layer 25 may be, for example, an epoxy resin mixed with silica fillers and phenol resins, and deposited before or after the re-flow process to establish the solder joints 50 and 55. A suitable thermal cure may be used.

The following description of the solder joint 50 will be illustrative of the other solder joints as well. The solder joint 50 includes a solder structure or bump 60 that is metallurgically bonded to another solder structure 65 that is sometimes referred to as a pre-solder. The solder bump 60 and the pre-solder 65 are metallurgically joined by way of a solder re-flow process. The irregular line 70 denotes the hypothetical border between the solder bump 60 and pre-solder 65 following the re-flow. However, the skilled artisan will appreciate that such a border 70 is seldom that readily visible even during microscopic examination. The solder bump 60 may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. The pre-solder 65 may be composed of the same types of materials. Optionally, the pre-solder 65 may be eliminated in favor of a single solder structure or a solder plus a conducting post arrangement.

The solder bump 60 may be metallurgically connected to a conductor structure 75 that is alternatively termed an underbump metallization or UBM structure. A portion of the UBM structure 75 projects through a polymer film 80 positioned on the passivation structure 45 and is in ohmic contact with a conductor pad 90 in the semiconductor chip 15. Another portion of the UBM structure 75 is seated on an outer surface of the polymer film 80. The polymer film 80 is designed to provide a compliant protective film and thus may be composed of a variety of materials, such as polyimide, benzocyclobutene or the like. An optional active terminal pad (not shown) may be interposed between the UBM structure 75 and the pad 90. The conductor pad 90 in the chip 15 may be part of plural chip metallization layers. Indeed, a few such conductors or traces are visible and labeled 95, 100 and 105, respectively. The conductor pad 90 may be used as an input/output site for power, ground or signals or may be used as a dummy pad that is not electrically tied to other structures. The pre-solder 65 is similarly metallurgically bonded to a conductor 110 that is bordered laterally by a solder mask 115. The conductor structure 110 of the circuit board 20 may form part of what may be multiple layers of conductor structures and interconnected by vias and surrounded by dielectric material layers (not shown) of the circuit board 20.

An additional polymer film 118 is applied to the polymer film 80. The polymer film 118 may be patterned selectively to establish multiple polymer portions that are not coextensive with the polymer film 80, such as the polymer film portion 120 proximate the solder joint 50 and the polymer film portion 122 proximate the solder joint 55. Note that only a portion of the polymer film portion 122 is visible in FIG. 2. Some or all of the solder interconnect structures 50, 55, etc. may be provided with such polymer film portions 120 and 122. The polymer film portion 120 provides compliant material over the UBM structure 75, which helps relieve stresses imparted on the UBM structure 75 by the solder joint 50. This stress buffering functionality may be particularly useful in circumstances where the solder joint 50 or at least the solder portion 60 is composed of a less compliant material, such as a lead free solder. The polymer film portion 122 serves the same function, albeit for the solder joint 55. Note also that the polymer film portions 120 and 122 and the other corresponding polymer film portions for the semiconductor chip 15 that are not visible, provide an underfill anchoring capability in the interstices, such as, for example, the interstice 125 between the polymer film portion 120 and the polymer film portion 122. These anchor spots provide a greater mechanical strength and reliability for the interface between the underfill 25 and the polymer film 80. The polymer film portions 120 and 122 may be composed of the same types of materials used for the polymer film 80.

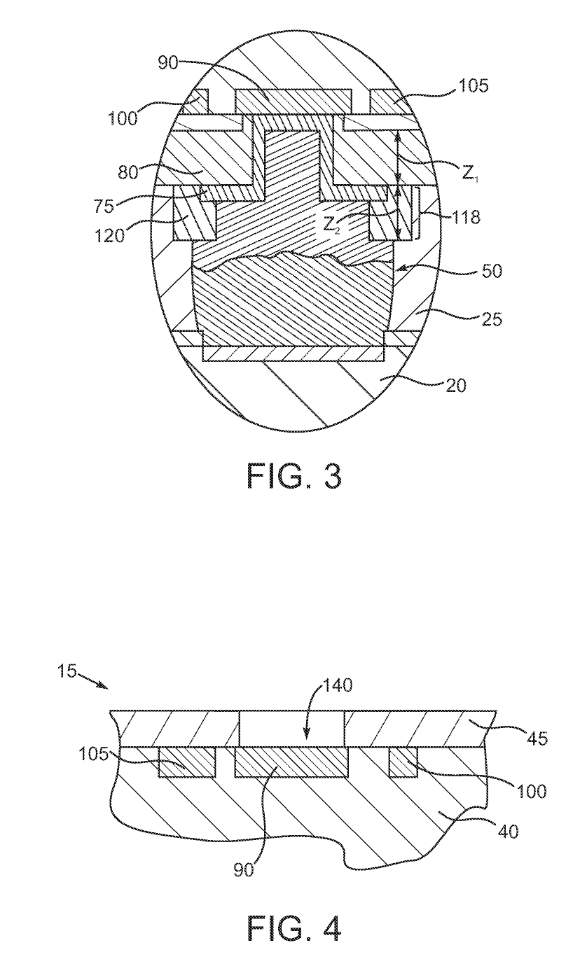

Additional details of the solder joint 50, the polymer film 80 and the polymer film portion 120 will be described in conjunction with FIG. 3, which is the portion of FIG. 2 circumscribed by the dashed oval 130 shown at greater magnification. Attention is now turned to FIG. 3. Note that due to the location of the dashed oval 130 in FIG. 2, FIG. 3 depicts a portion of the circuit board 20, the underfill 25, the solder joint 50, the polymer film 80, the polymer film portion 120 of the polymer film 118, the UBM structure 75, the conductor traces 100 and 105 and the conductor pad 90. The polymer film 80 may be provided with some thickness, Z₁, which is selected to be advantageously thick enough to provide a desirably low capacitance between the UBM structure 75 and the underlying traces 100 and 105, for example. Indeed, the polymer film 80 may be of such thickness and dielectric constant that the UBM structure 75 can serve as a routing layer. While the ultimate thickness, Z₁, will depend upon minimum device geometries and processing techniques, in an exemplary embodiment, the layer 80 may have a thickness, Z₁, of about 4 to 12 μm. The polymer film portion 120 may have some thickness, Z₂, which may be the same or different than the thickness, Z₁.

An exemplary method for fabricating the exemplary UBM structure 75 and the polymer film portion 120 may be understood by referring now to FIGS. 4, 5, 6, 7, 8, 9, 10, 11, 12 and 13 and initially to FIG. 4. The techniques will be illustrative of the other solder joints and polymer film portion(s) 122. FIG. 4 is a sectional view that shows a small portion of the semiconductor device layer 40 of the semiconductor chip 15, the conductor pad 90 and traces 100 and 105, and the passivation structure 45. It should be understood that FIG. 4 depicts the semiconductor device layer 40 and the conductor pad 90 flipped over from the orientation depicted in FIGS. 2 and 3. It should also be understood that the process described herein could by performed at the wafer level or on a die by die basis. At this stage, conductor pad 90 and the passivation structure 45 have been formed. The conductor pad 90 may be composed of a variety of conductor materials, such as aluminum, copper, silver, gold, titanium, refractory metals, refractory metal compounds, alloys of these or the like. In lieu of a unitary structure, the conductor pad 90 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductor pad 90. Various well-known techniques for applying metallic materials may be used, such as physical vapor deposition, chemical vapor deposition, plating or the like. It should be understood that additional conductor structures could be used.

The passivation structure 45 may consist of alternating layers of dielectric materials, such as silicon dioxide and silicon nitride, polymeric materials or the like, and may be formed by well-known chemical vapor deposition (CVD), oxidation or other techniques. A suitable lithography mask (not shown) may be formed on the passivation structure 45 and by well-known lithography steps patterned with a suitable opening in alignment with the conductor pad 90. Thereafter, one or more material removal steps may be performed in order to produce an opening 140 in the passivation structure 45 so that the conductor pad 90 is exposed. For example, the material removal steps may include one or more dry and/or wet etching processes suitable for the particular materials selected for the passivation structure 45. Following the material removal to yield the opening 140, the mask (not shown) may be stripped by ashing, solvent stripping or the like.

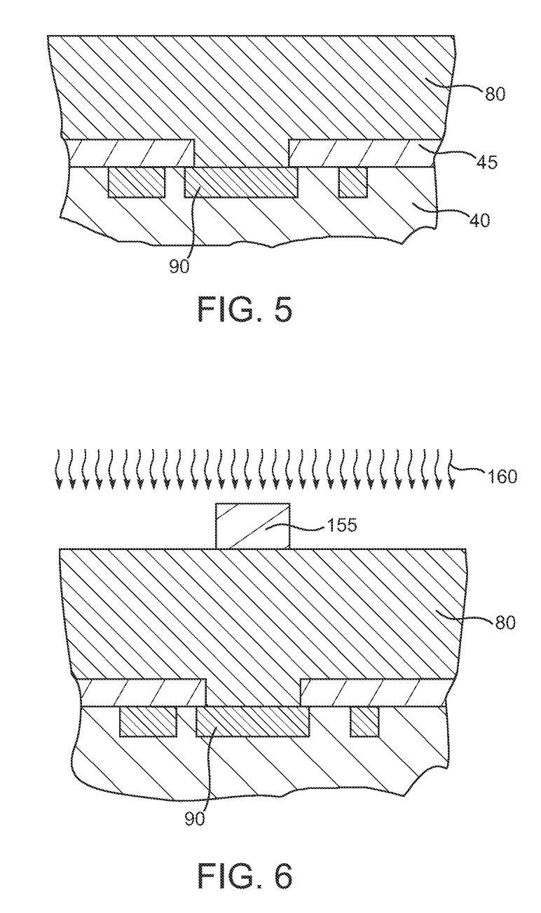

With the opening 140 established in the passivation structure 45 and the conductor pad 90 exposed, fabrication of the polymer film 80 can proceed. As shown in FIG. 5, the polymer film 80 is applied over the passivation structure 45 and the exposed portion of the conductor pad 90. The polymer film 80 may be composed of polyimide, benzocyclobutene or the like, or other insulating materials such as silicon nitride or the like and may be deposited by spin coating, CVD or other techniques.

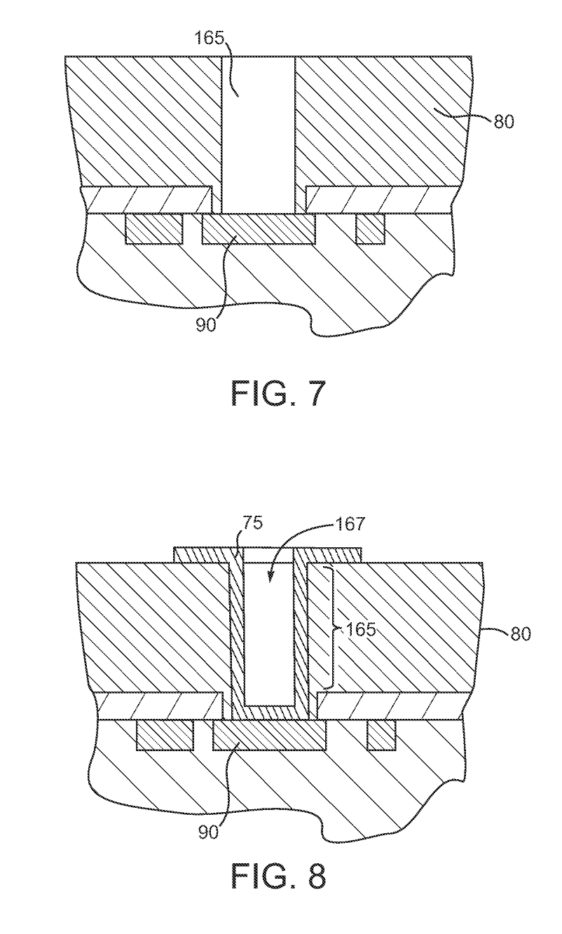

Referring now to FIG. 6, the polymer film 80 may be lithographically patterned to establish a suitable opening for the later-formed UBM structure 75 shown in FIG. 2. This may be done in a variety of ways depending on the composition of the polymer film 80. A polyimide polymer film 80 may be infused with a photoactive compound(s) lithographically patterned and subjected to material deposition or plating processes. In this illustrative embodiment, the polymer film 80 does contain photoactive compounds. A non-contact mask 155 is positioned on the polymer film 80 in alignment with the conductor pad 90. An exposure with suitable radiation 160 is then performed. The portions of the polymer film 80 not covered by the mask 155 are rendered insoluble in a developer solution. Referring now to FIG. 7, the non-contact mask 155 shown in FIG. 6 is removed and the polymer film 80 developed to yield an opening 165 exposing a portion of and generally aligned with the conductor pad 90. A bake cure of the polymer film 80 follows the developing process. If the polymer layer 80 is not capable of material removal by way of exposure and developing, then a suitable lithography mask may be applied and an etch performed to yield the requisite opening 165.

The fabrication of the UBM structure 75 will now be described in conjunction with FIG. 8. The skilled artisan will appreciate that a UBM structure is designed to bond to an overlying solder bump or other solder structure, to establish a conductive interface with an underlying conductor structure, in this case the conductor pad 90, to bond as necessary with underlying or surrounding dielectrics, all while providing a barrier to the diffusion of solder constituents into underlying conductor structures, which might otherwise degrade those conductor structures. UBM structures may use multiple films of different compositions depending on the type of solder application process. In this illustrative embodiment, the UBM structure 75 may be formed as a series of films applied in succession. For a printed solder bump, initially a titanium or titanium-tungsten film may be sputtered deposited on the polymer film 80 as well as along the sidewalls of the opening 165 and on the conductor pad 90. The titanium film serves as an adhesion layer to readily adhere to the polymer film 80. Next, a barrier layer composed of nickel, nickel-vanadium or other materials is plated or otherwise deposited on the titanium film. Finally, a solder-wettable layer composed of copper, gold or other materials is applied to the nickel film by plating, sputter deposition or other techniques. Following material deposition, a wet etch is performed to yield the patterned UBM 75 as shown in FIG. 8. However, in the event that a bump plating process is used to establish later formed solder bumps, then the UBM structure 75 may consist of an adhesion layer of the type described above, followed by a plating seed layer, such as copper deposited by electroless plating or sputter deposition, followed by a nickel or nickel-vanadium barrier layer of the type described above and capped with a plating bar of copper of the like. For a plated bump process, a wet etch is similarly performed. However, the barrier film of nickel or nickel-vanadium will typically be localized thus not need etch patterning. Depending on the thicknesses of the deposited/plated materials, the UBM structure 75 may have an internal cavity 167.

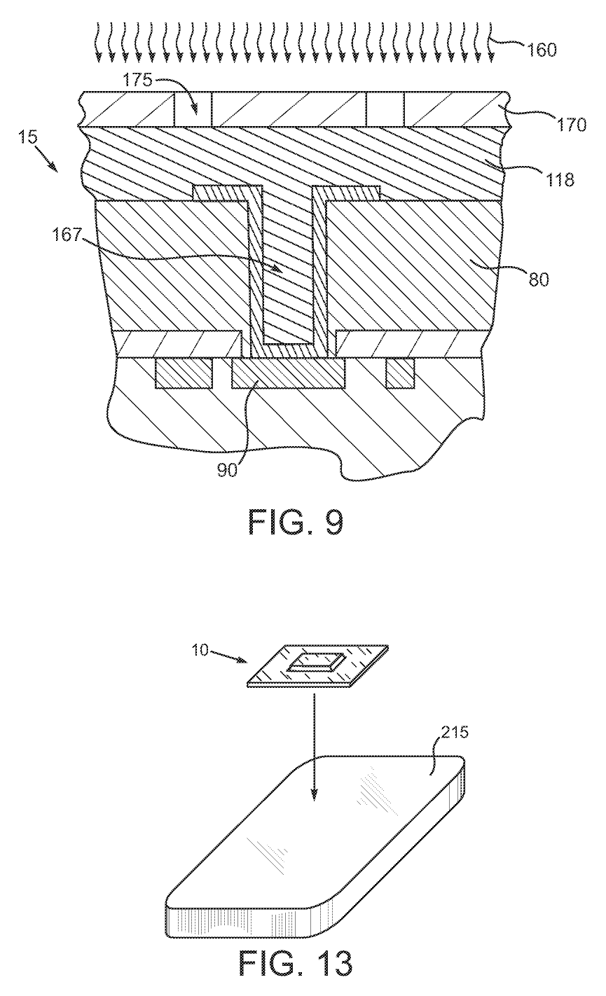

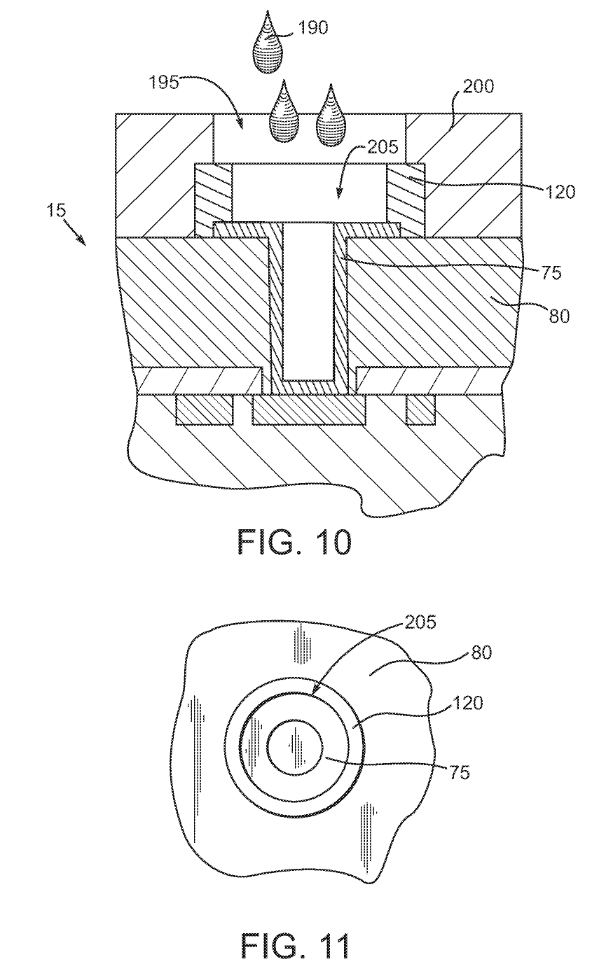

Referring now to FIG. 9, the polymer film 118 may be applied to the polymer film 80 and over the underbump structure 75. The polymer film 118 will be subsequently patterned to yield the polymer film portion 120 (see FIG. 2 and any others like it). Spin coating or other application techniques may be used to apply the polymer film 118. Note that the cavity 167 of the UBM structure 75 will be filled with a portion of the polymer film 118. In order to pattern the polymer film 118 into the island-like polymer film portions 120 and 122 structure depicted in FIGS. 2 and 3, lithographic patterning may be used. This may be done in a variety of ways depending on the composition of the polymer film 118. A polyimide polymer film 118 may be infused with a photoactive compound(s) lithographically patterned and subjected to material deposition or plating processes. In this illustrative embodiment, the polymer film 118 does contain photoactive compounds. A suitable non-contact mask 170 may be applied to the polymer film 118 and patterned with an opening 175, which may have a ring-like footprint when viewed from above. The opening 175 is designed to enable the unmasked portions of the polymer film 118 to be exposed to the exposure radiation 160 and thus be rendered insoluble in a suitable developer solution. The opening 175 is sized so that any polymer material is completely removed from the cavity 167 in advance of a solder deposition process. Following the application of exposure radiation 160 and a suitable developing process the non-contact mask 170 may be removed to leave the patterned polymer film portion 120 as shown in FIG. 10. A bake cure is next performed on the polymer film portion 120.

At this stage for a printed bump process, solder 190 may be applied to the UBM structure 75 through an opening 195 patterned in a removable stencil 200 composed of resist or other mask materials and an opening 205 defined by the polymer film portion 120 to establish the solder structure 60 depicted in FIGS. 2 and 3. The stencil 200, applied to the polymer film 80 and a portion of the polymer film portion 120, may be removed by ashing, solvent stripping or both following deposition of the solder 190 and a reflow performed. Following the application of the solder 190 to establish the solder structure 60 depicted in FIGS. 2 and 3, the semiconductor chip 15 may be brought into proximity with the circuit board 20 and a suitable reflow performed in order to establish the solder joint 50.

FIG. 11 is a plan view of the polymer film 80, the polymer film portion 120, the opening 205 in the polymer film portion 120 and the UBM structure 75 prior to application of the stencil 200 and the solder material 190 depicted in FIG. 11. Here, the UBM structure 75 and the polymer film portion 120 may have a generally circular footprint. However, the skilled artisan will appreciate that virtually any other shape may be used for both the UBM structure 75 and the polymer film portion 120.

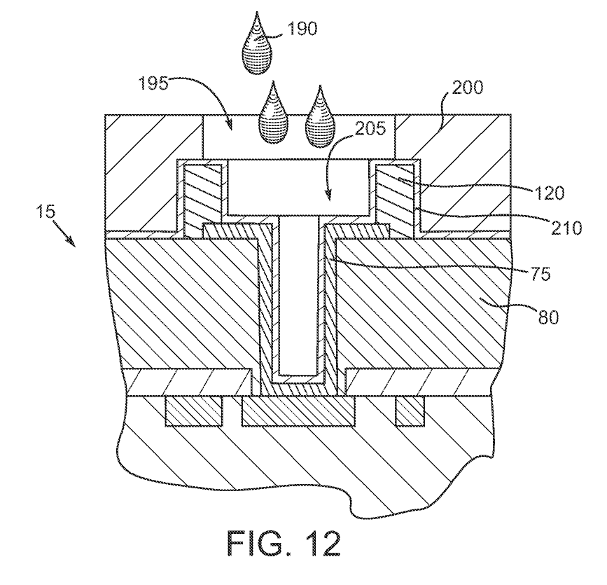

For a plated bump process, a suitable plating bar 210 composed of copper or the like may be sputter or otherwise deposited over the polymer layers 80 and 120 and the exposed portion of the UBM structure 75 prior to application of the stencil 200 as shown in FIG. 12. With the stencil 200 in place, solder 190 may be plated on the exposed portions of the plating bar 210, namely where the openings 195 and 205 are positioned. Following the plating process, the stencil 200 may be removed by ashing, solvent stripping or both, portions of the plating bar 210 lateral to the polymer film portion 120 removed by wet etch and a solder reflow performed. Establishment of the solder joint 50 shown in FIGS. 2 and 3 may be proceed as describe above for a printed process.

As shown in FIG. 13, the semiconductor chip device 10 may be mounted in a electronic device 215. The electronic device 215 may be a computer, a digital television, a handheld mobile device, a personal computer, a server, a memory device, an add-in board such as a graphics card, or any other computing device employing semiconductors.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
applying a first polymer film to a side of a semiconductor chip;
forming a first underbump metallization structure with at least a portion on the first polymer film; and
applying a second polymer film on the first polymer film with an opening exposing a portion of the first underbump metallization structure.

2. The method of claim 1, wherein the second polymer film is not coextensive with the first polymer film.

3. The method of claim 1, comprising coupling a solder structure to the first underbump metallization structure.

4. The method of claim 3, wherein the solder structure comprises one of a solder bump and a solder joint.

5. The method of claim 3, comprising electrically coupling a circuit board to the solder structure.

6. The method of claim 5, wherein the circuit board comprises a semiconductor chip package substrate.

7. The method of claim 1, comprising applying the first and second polymer films using instructions stored in a computer readable medium.

8. The method claim 1, wherein the forming the first underbump metallization structure comprises forming a opening in the first polymer film and partially filling the opening with a portion of the first underbump metallization structure.

9. The method of claim 1, comprising forming a second underbump metallization structure on the first polymer film, the applying the second polymer film comprising patterning a first polymer film portion proximate the first underbump metallization structure and a second polymer film portion proximate the second underbump metallization structure spaced apart from the first polymer film portion to leave an interstice.

10. The method of claim 9, comprising filling the interstice with an underfill material.

11. A method of coupling a semiconductor chip to a circuit board, the semiconductor chip having a first polymer film, a first underbump metallization structure with at least a portion on the first polymer film, and a second polymer film on the first polymer film with an opening exposing a portion of the first underbump metallization structure, comprising:
coupling a solder structure to the first underbump metallization structure; and
coupling the solder structure to the circuit board.

12. The method of claim 11, wherein the solder structure comprises one of a solder bump and a solder joint.

13. The method of claim 11, wherein the coupling the solder structure to the circuit board comprises coupling the solder structure to a presolder coupled to the circuit board.

14. The method of claim 11, wherein the circuit board comprises a semiconductor chip package substrate.

15. The method of claim 11, comprising forming a second underbump metallization structure on the first polymer film, the applying the second polymer film comprising patterning a first polymer film portion proximate the first underbump metallization structure and a second polymer film portion proximate the second underbump metallization structure spaced apart from the first polymer film portion to leave an interstice.

16. The method of claim 15, comprising filling the interstice with an underfill material.

17. An apparatus, comprising:
a semiconductor chip;
a first polymer film on the semiconductor chip;
a first underbump metallization structure with at least a portion on the first polymer film; and
a second polymer film on the first polymer film with an opening exposing a portion of the first underbump metallization structure.

18. The apparatus of claim 17, comprising a solder structure coupled to the first underbump metallization structure.

19. The apparatus of claim 18, wherein the solder structure comprises one of a solder bump and a solder joint.

20. The apparatus of claim 17, comprising a circuit board coupled to the semiconductor chip.

21. The apparatus of claim 17, wherein the semiconductor chip comprises a second underbump metallization structure on the first polymer film and second polymer film comprises a first polymer film portion proximate the first underbump metallization structure and a second polymer film portion proximate the second underbump metallization structure spaced apart from the first polymer film portion to leave an interstice.

22. The apparatus of claim 21, comprising an underfill material in the interstice.
